(19) United States
(12) Patent Application Publication
(10) Pub. No.: US 2016/0079454 A1
(43) Pub. Date: Mar. 17, 2016

(54) FORMATION OF A I-III-VI2 SEMICONDUCTOR LAYER BY HEAT TREATMENT AND CHALCOGENIZATION OF AN I-III METALLIC PRECURSOR

(71) Applicant: NEXCIS, Rousset (FR)

(72) Inventors: Cedric Broussillou, Rousset (FR); Sylvie Bodnar, Rousset (FR)

(73) Assignee: NEXCIS, Rousset (FR)

(21) Appl. No.: 14/888,786

(22) PCT Filed: Apr. 30, 2014
(86) PCT No.: PCT/FR2014/051030

§ 371 Date: Nov. 3, 2015

(30) Foreign Application Priority Data
May 3, 2013 (FR) 13 54112

(51) Int. Cl. H01L 31/032; H01L 21/677; F27D 7/06; H01L 31/036; F27B 9/10; H01L 31/18; H01L 21/67

(52) U.S. Cl. CPC H01L 31/0322; H01L 31/18; H01L 21/677; H01L 21/67109; H01L 21/67248; H01L 31/036; F27B 9/10; F27D 7/06; F27D 2019/0093

(57) ABSTRACT

A process for forming a semiconductor layer, especially with a view to photovoltaic applications, and more particularly to a process for forming a semiconductor layer of I-III-VI₂ type by heat treatment and chalcogenization of a metallic precursor of I-III type, the process comprising: a heating step under an inert atmosphere during which the temperature increases uniformly up to a first temperature of between 460° C. and 540° C., in order to enable the densification of the metallic precursor, and a chalcogenization step beginning at said first temperature and during which the temperature continues to increase up to a second temperature, a stabilization temperature, of between 550° C. and 600° C., in order to enable the formation of the semiconductor layer. The formation of a semiconductor layer, or equivalently of an absorber, having a gain in conversion efficiency of around 4%, is thus advantageously achieved.

The invention relates to the field of industrial processes for forming a semiconductor layer, in particular for photovoltaic applications.

The invention relates more particularly to a process for forming a type I-III-VI₂ semiconductor layer by heat treatment and chalcogenization, in at least one furnace chamber, of a type I-III metal precursor deposited on a substrate.

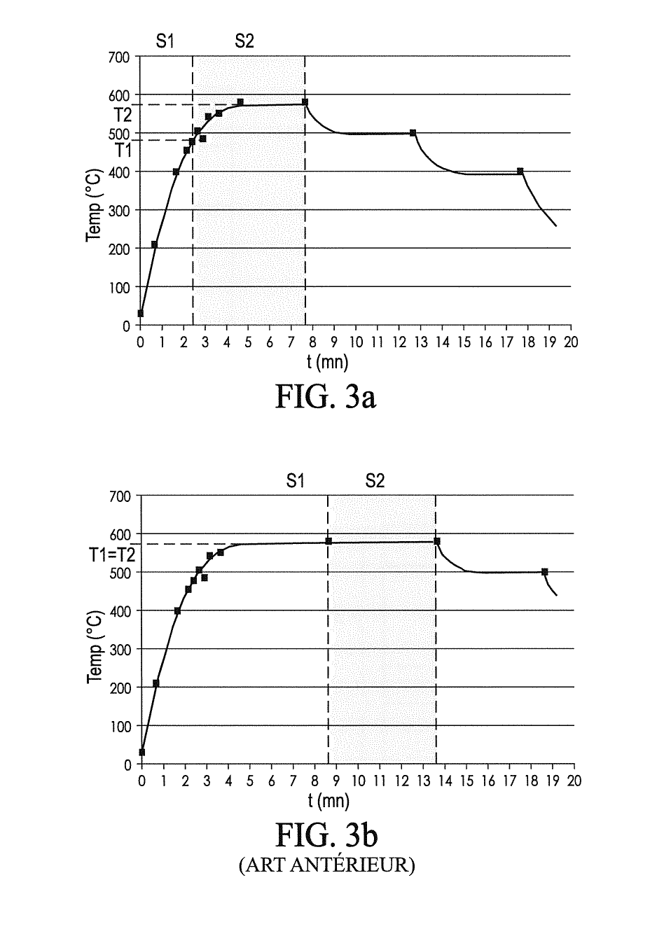

As illustrated in FIG. 3b, such a formation process usually includes a step S1 of heating the type I-III metal precursor to a stabilization temperature of between 550° C. and 600° C., and more particularly equal to 580° C., then a chalcogenization step S2 during which the temperature is maintained at said stabilization temperature.

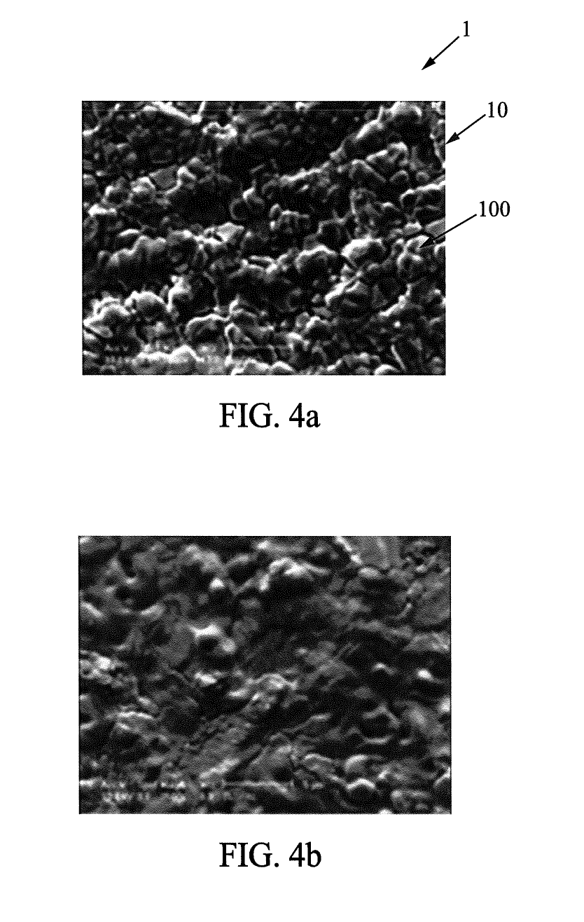

As shown in the photograph of FIG. 4b, the type I-III- VI₂ semiconductor layer obtained has a microstructure in which the grains are poorly defined. It should be noted that the microstructure includes a mixture of two phases, one of composition CuIn_{0.8}Ga_{0.2}Se₂, the other of composition CuIn_{0.5}Ga_{0.5}Se₂.

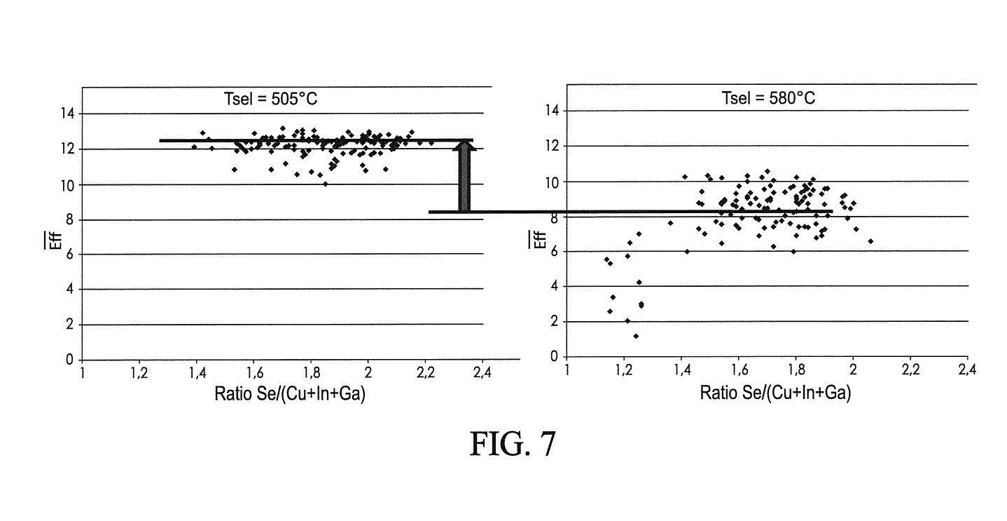

In addition, as represented in FIG. 7, the semiconductor layer so formed is used to create photovoltaic cells having a conversion efficiency which:
varies according to the ratio of the total molar amount of chalcogen incorporated into the substrate and precursor to the molar amount of I-III precursor, particularly when the value of this ratio varies between 1.2 and 2.0, and
is limited to a value of less than 9%.

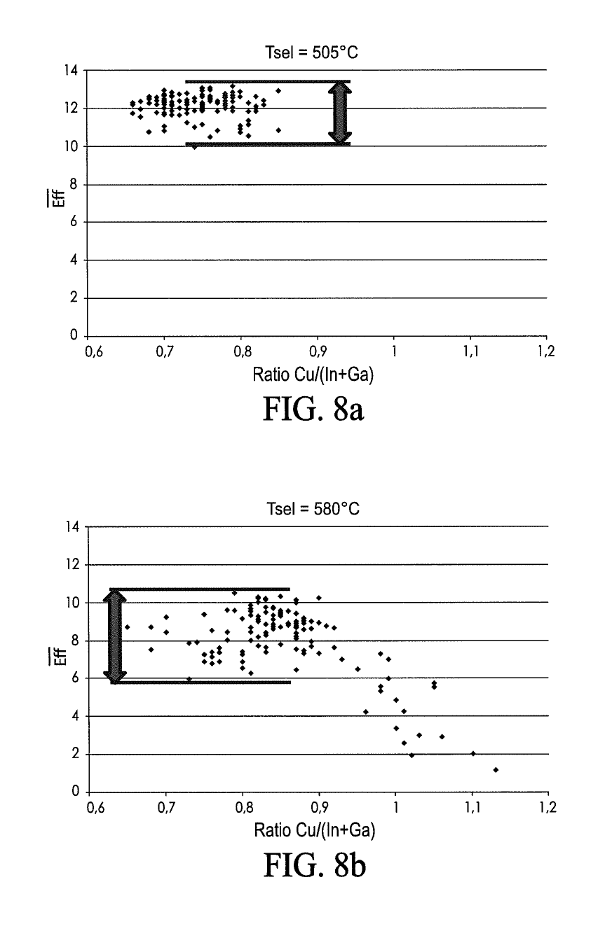

In addition, as represented in FIG. 8b, the semiconductor layer so formed is used to create photovoltaic cells having a conversion efficiency which varies according to the ratio of the molar amount of copper to the molar amount of gallium and indium in the metal precursor, particularly when the value of this ratio varies between 0.6 and 1.2 with significant dispersion between 5% and 11%.

In this context, the present invention improves the situation by overcoming one or more of the limitations mentioned above.

To this end, the process of the invention, which is otherwise in accordance with the preamble provided above, is essentially such that it comprises:
a heating step under an inert atmosphere, during which the temperature uniformly increases to a first temperature of between 460° C. and 540° C., to enable densification of the precursor, and
a chalcogenization step beginning at said first temperature and during which the temperature continues to increase to a second temperature, for stabilization, of between 550° C. and 600° C., to enable formation of the semiconductor layer.

The process thus advantageously enables formation of a semiconductor layer offering a gain of around 4% in conversion efficiency compared to a semiconductor layer formed according to the formation process illustrated in FIG. 3b.

According to one feature of the invention, the first temperature is between 480° C. and 520° C.

According to another feature, the first temperature is equal to 505° C.

The formation process is thus advantageously optimized according to the temperature at which the chalcogenization step begins.

According to another feature, during the heating step, the temperature increases at a rate of 3.5° C./sec, plus or minus 1° C./sec.

The process thus advantageously enables finely tuned control of densification of the metal precursor.

According to another feature, the chalcogenization step consists of a selenization step by injection of a gaseous mixture of selenium and dinitrogen into at least one furnace chamber.

The process thus advantageously enables selenization of the metal precursor at a chosen moment in the evolution of the temperature over time.

According to another feature of this chalcogenization step, the gaseous mixture of selenium and nitrogen is obtained by heating selenium to a temperature of 500° C., plus or minus 20° C., to obtain a high partial pressure of the selenium.

The process thus advantageously makes it possible to optimize the amount of selenium that can be captured in the semiconductor layer formed, relative to the amount of copper in the metal precursor, and enables formation of a semiconductor layer at an industrial rate.

In another feature of this chalcogenization step, injection of the gaseous mixture of selenium and dinitrogen occurs at a volumetric flow rate of 13 standard liters per minute, plus or minus 3 standard liters per minute.

According to another feature, the chalcogenization step lasts 5 minutes, plus or minus 1 minute.

The process thus advantageously enables formation of a semiconductor layer at an industrial rate.

According to another feature, the ratio of the total amount of chalcogen incorporated into the substrate and precursor to the amount of metal precursor is between 1.4 and 2.2.

The process advantageously provides satisfactory stability of the formed semiconductor layer within this range of values for said ratio.

According to another feature, the furnace comprises at least one series of chambers, and the heating step is carried out in a first chamber of the series and the chalcogenization step is carried out in a second chamber of the series.

According to another feature, at least the second chamber of the furnace is maintained at a pressure that is 20 to 200 Pa below atmospheric pressure.

The process thus advantageously ensures a satisfactory level of safety.

According to another feature, the second temperature (the stabilization temperature) is between 570° C. and 590° C.

The invention also relates to a type I-III-VI₂ semiconductor layer obtained by the process according to any of the features set forth above.

According to one feature of said semiconductor layer, it has a microstructure composed of grains of different sizes corresponding to a full width at half maximum of the {112} XRD peak of the CIGSe of between 0.16° and 0.18°.

The semiconductor layer, or equivalently the absorber, thus preferably provides a gain in conversion efficiency of about 4% compared to a semiconductor layer formed according to the formation process illustrated in FIG. 3b. In addition, the semiconductor layer thus advantageously offers satisfactory microstructural homogeneity.

According to another feature of the semiconductor layer, it comprises several layers of different compositions, including a lower layer which is a CuGaSe₂ layer.

The semiconductor layer thus advantageously grips the carrier layers more securely, and in particular a layer of MoSe₂ composition.

The invention further relates to a furnace for carrying out the process according to one of its features set forth above.

Said furnace comprises:
at least a first chamber and a second chamber,
means of conveyance from one chamber to the next,
a heating device for each chamber,
control means for each heating device, and
measurement means for measuring the temperature in each chamber,

the latter communicating the temperature measurements for each chamber to the control means for the purposes of controlling each heating device, so as to ensure a uniform increase in temperature in the first chamber to a first temperature of between 460° C. and 540° C., and the maintaining of the temperature in the second chamber at a second temperature, for stabilization, of between 550° C. and 600° C., said furnace further comprising injection means for injecting an inert gas into the first chamber, and

said furnace further comprising injection means for injecting, into the second chamber, a gaseous mixture of selenium and dinitrogen having a temperature of between 480° C. and 520° C.

Other features and advantages of the invention will become apparent from the following description provided for indicative and non-limiting purposes, with reference to the accompanying drawings, wherein:

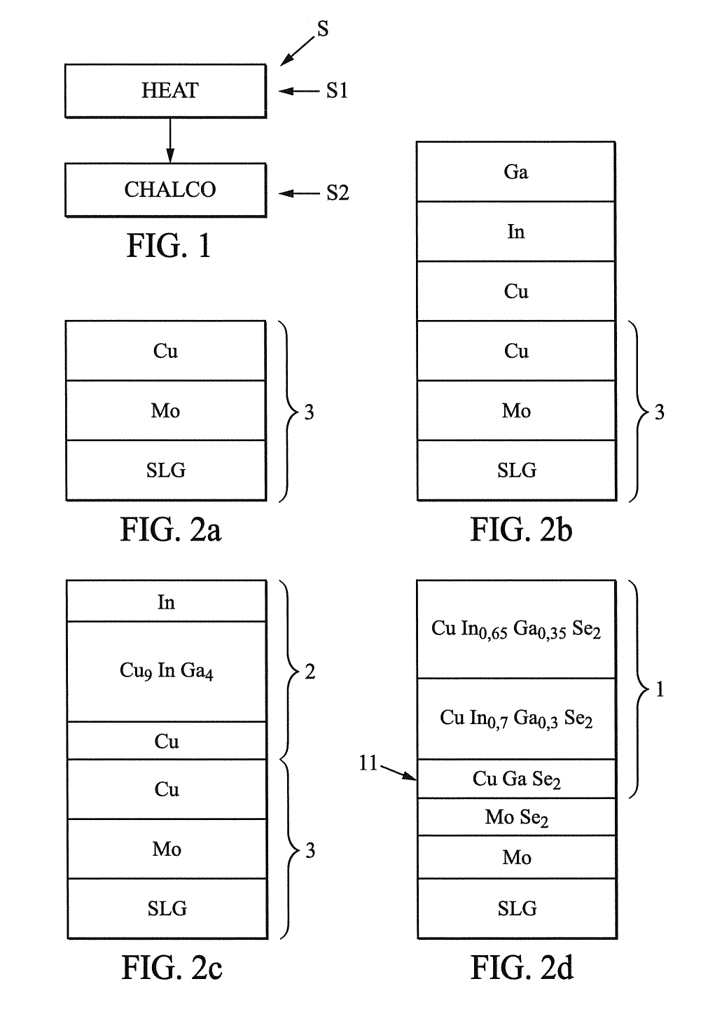

FIG. 1 very schematically represents the formation process comprising a heating step and a chalcogenization step, according to both the prior art and to the invention,

FIGS. 2a to 2d show different stacks of layers corresponding to different phases of the formation process according to the invention,

FIGS. 3a and 3b are graphs showing the change in temperature over time within the furnace, illustrating the start and end of the chalcogenization step of the formation process according to the invention and to the prior art respectively,

FIGS. 4a and 4b are photographs, obtained by microscopy, of the microstructures formed by the formation processes according to the invention and to the prior art respectively,

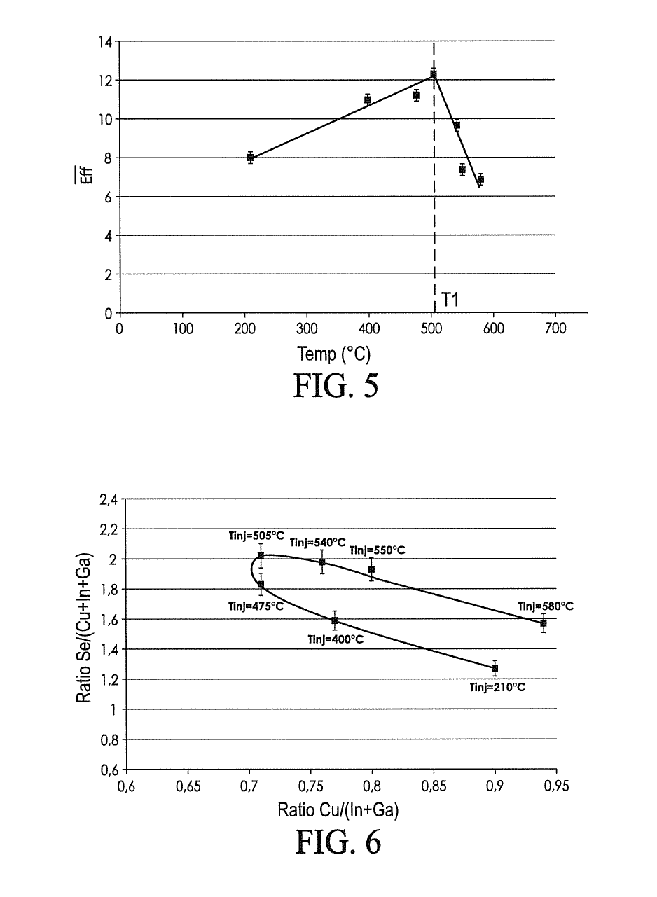

FIG. 5 shows a graph of the evolution of the average yield, or equivalently of the average conversion efficiency, of photovoltaic cells obtained for different starting temperatures of the chalcogenization,

FIG. 6 shows a graph obtained by X-ray fluorescence spectrometry (XRF) showing the evolution of the ratio of the total amount of selenium incorporated into the substrate and precursor to the amount of metal precursor, as a function of the ratio of the amount of copper to the amount of indium and gallium in the metal precursor, for different temperatures of the gaseous mixture of selenium and dinitrogen injected into the furnace chamber,

FIG. 7 shows two graphs side by side, each of these two graphs plotting measurements of photovoltaic cell conversion efficiency as a function of the ratio of the molar amount of chalcogen agent to the molar amount of metal precursor; the right graph shows measurements collected on photovoltaic cells formed according to the formation process of the prior art, and the left graph shows measurements collected on photovoltaic cells formed by the formation process according to the invention,

FIGS. 8a and 8b are adjoining graphs, each representing the photovoltaic cell conversion efficiency as a function of the ratio of the molar amount of copper to the molar amount of gallium and indium in the metal precursor, in particular when this ratio varies between 0.6 and 1.2, said photovoltaic cells being respectively obtained by the formation process of the invention and by the formation process of the prior art,

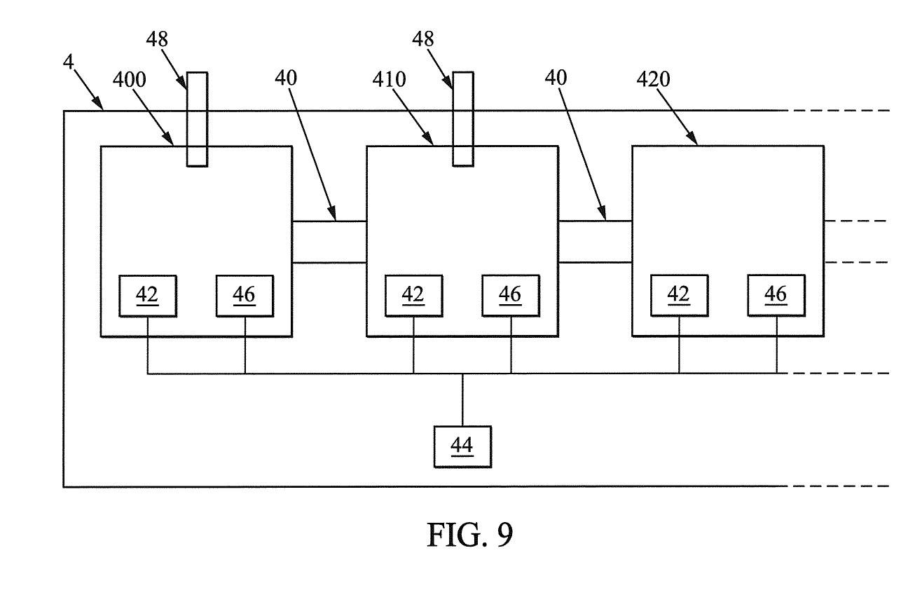

FIG. 9 schematically represents a furnace for carrying out the process according to the invention, and

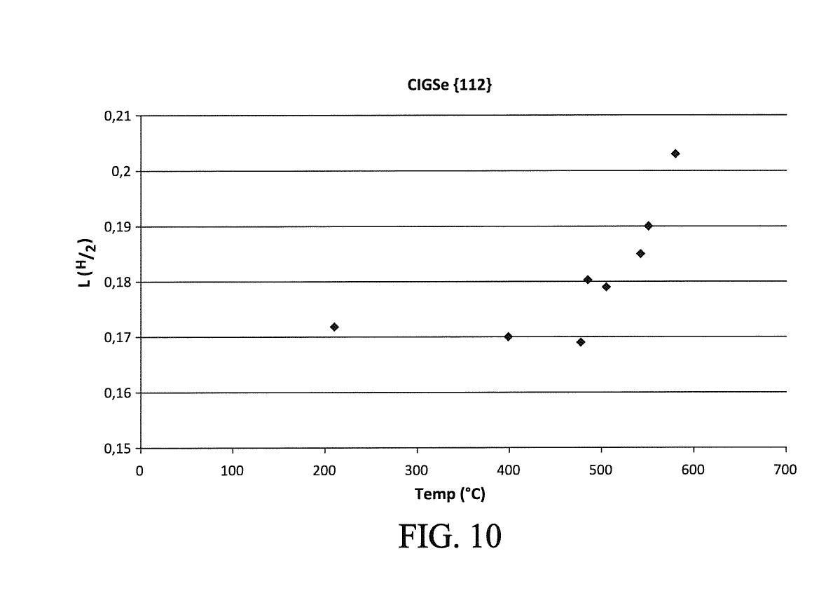

FIG. 10 shows a graph illustrating measurements of the full width at half maximum of the {112} XRD peak of the CIGSe obtained by X-ray diffraction (XRD), for different values of the starting temperature of the chalcogenization.

In the following description, each layer is described as formed or deposited “on” or “under” another layer or component, which means that this layer may be formed “directly” or “indirectly” (with another layer or component between) on or under another layer or another component. In addition, relative criteria such as “lower”, “upper”, or “intermediate” define each layer as illustrated in the accompanying drawings.

In the drawings, the thickness or size of each layer is exaggerated or omitted or only schematically represented for the purposes of convenience and clarity of the explanation. In addition, the thickness or size of each layer does not reflect its actual size or thickness.

The formation process S firstly comprises the providing of a substrate 3. The substrate has, for example, a width and length equal to 60 cm and 120 cm to provide a surface area of 7200 cm².

As illustrated in FIG. 2a, the substrate 3 is composed of a mechanical support and a conductive layer such as a molybdenum film. It comprises, for example, a lower layer of glass (SLG), an intermediate layer of molybdenum (Mo), and an upper layer of copper (Cu). The copper layer is deposited, for example, by the physical vapor deposition (PVD) technique.

Next, the formation process S comprises a step of depositing on the substrate 3 a stack of layers of group IB and IIIA elements, such as copper (Cu) and indium (In) respectively. Another group IIIA element, more particularly gallium, can also be used in association with the indium and copper. The use of gallium makes it possible to increase the energy band, the open circuit voltage (OCV), and the conversion efficiency of the photovoltaic cells formed. In addition, it should be noted that gallium has a melting point of 29.8° C., which is close to room temperature, meaning it has high diffusion; its concentration profile in the semiconductor layer 1 to be formed must therefore be closely controlled, which is what the present process intends to achieve, particularly by continuous control of the temperatures to which the different stacks of layers are exposed during the various phases of the formation process, as illustrated in FIGS. 2a to 2d.

As illustrated in FIG. 2b, said stack comprises for example a first layer of copper (Cu) deposited on the substrate 3, a second layer of indium (In) deposited on the first layer of copper (Cu), and a third layer of gallium (Ga) deposited on the second layer of indium (In). By way of non-limiting example, the ratio of the molar amount of copper to the molar amount of gallium and indium is between 0.65 and 0.95.

By way of non-limiting example, the deposition step consists of a step of electrodeposition of at least one of the layers of the stack. All the layers of group IB and IIIA elements can advantageously be electrodeposited, electrodeposition being an industrial deposition technique that is particularly fast and inexpensive.

In addition, it should be noted that the layers of the stack are preferably electrodeposited, at least in the sense that the values of the parameters of the various heat treatments said below to be preferred are particularly suited to this technique. Depositing at least one layer of the stack by physical vapor deposition for example is likely to result in having to specifically identify other preferred values for these parameters, although these are likely to remain within the range of values shown below, in particular by retaining the principle in the sense of the invention of uniformly increasing the temperature, followed by a plateau, during the heating S1 and chalcogenization S2 steps.

Next, the formation process S comprises an annealing step to form the type I-III metal precursor 2 on the substrate 3.

The annealing step at least consists of heating the stack of layers of group IB and IIIA elements on substrate 3 to a temperature between 80° C. and 110° C., preferably 90° C., which is maintained for 20 to 40 minutes, preferably 30 minutes, to allow interdiffusion between the layers.

This annealing is said to be “soft” because the maximum annealing temperature is relatively low and therefore its duration can be relatively long. For example, adequate diffusion of the gallium layer through the indium layer to the substrate 3 is thus achieved.

As shown in FIG. 2c, the type I-III metal precursor 2 so formed can be composed of a lower layer of copper, an intermediate layer of composition Cu₉InGa_{4,} and an upper layer of indium.

The “soft” annealing step can end with a phase of cooling to ambient temperature.

As illustrated in FIG. 1, the process S of forming a type I-III-VI₂ semiconductor layer 1 by heat treatment and chalcogenization of the type I-III metal precursor 2 comprises:
a heating step S1 under inert atmosphere to enable densification of the metal precursor 2, and
a chalcogenization step S2 to enable formation of the semiconductor layer 1, or equivalently of the absorber.

Densification of the metal precursor is understood here to mean a reorganization of the metal atoms, resulting in a mixture of dense alloys which contain phases containing only I and III elements as well as mixed phases of I-III elements, without creating porosities.

The present invention further relates to a furnace 4 for carrying out at least the heating S1 and chalcogenization S2 steps described below.

As illustrated in FIG. 9, the furnace 4 comprises:

at least a first chamber 400 and second chamber 410,

means of conveyance 40, or conveyor, from one chamber to the next,

a heating device 42 for each chamber,

control means 44, or controller, for each heating device 42, and

measurement means 46, or sensors, for measuring the temperature in each chamber 400, 410.

The temperature measurement means 46 communicate the temperature measurements for each chamber 400, 410, 420 to the control means 44. The control means control each heating device 42 to ensure at least, in the first chamber 400, a uniform increase in temperature to a first temperature T1 of between 460° C. and 540° C., and in the second chamber 410, that the temperature is maintained at a second temperature T2, for stabilization, of between 550° C. and 600° C.

In its broadest sense, the heating step S1 under an inert atmosphere consists of a step in which the temperature increases uniformly to the first temperature T1 of between 460° C. and 540° C. The first temperature T1 may more particularly be between 480° C. and 520° C., and is preferably equal to 505° C.

More particularly, the fact that the heating step S1 is carried out under an inert atmosphere is understood to mean that the chamber 400 or chambers of the furnace in which the heating step S1 is performed is or are filled with an inert gas such as dinitrogen, of formula N₂, and contain no selenium.

So that the heating step S1 is carried out under an inert atmosphere, the furnace 4 may comprise injection means 48, or an injector, for injecting inert gas into the first chamber 400.

It is possible to achieve a uniform temperature increase in a furnace 4 with multiple chambers which an object to be heated travels between. The temperature of each chamber is controlled, for example via the control means 44, to have an appropriate thermal profile. In practice, step S1 occurs in a chamber 400 or in a series of multiple chambers.

It should be noted, by way of illustrative examples, that the heating step S1 starts at the final “soft” annealing temperature, meaning at a temperature of between 80° C. and 110° C., preferably equal to 90° C., if the “soft” annealing does not include a cooling phase, or at ambient temperature if the “soft” annealing includes a cooling phase to ambient temperature. In the heat treatment example illustrated in FIGS. 3a and 3b, the heating step S1 starts at ambient temperature.

The fact that the temperature increases uniformly is understood here to mean that the temperature increases according to an increasing function that is continuous and differentiable at all points of the time interval considered.

After that, the temperature does not increase according to an increasing function and continues in segments and plateaus for the interval concerned.

According to a particular embodiment of the heating step S2, the temperature increases at a rate between 2.5° C./sec and 4.5° C./sec, and preferably at a rate of 3° C./sec. This rate is either an average rate for the time interval concerned or is an instantaneous rate at a point in this interval, within the limitations of the uniform increase in temperature as defined above.

In the examples illustrated in FIGS. 3a and 3b, showing the evolution of the temperature over time in said at least one chamber of the furnace, it can be seen that the temperature increases in a nearly affine manner between 20° C. and 180° C. at a rate of 4° C./sec, while between 20° C. and 505° C. the average rate is 3.2° C./sec.

In its broadest sense, the chalcogenization step S2 starts at said first temperature T1 and, during this step S2, the temperature continues to increase to a second temperature T2, the stabilization temperature, of between 550° C. and 600° C. Stabilization temperature is understood to mean a temperature which, once reached, remains constant for a defined time.

Thus, in the example illustrated in FIG. 9, the second chamber 410 of the furnace 4 is maintained at the second temperature T2.

The second temperature T2 is more particularly between 570° C. and 590° C., and is preferably equal to 580° C.

According to one embodiment of the chalcogenization step S2, the chalcogen is selenium and the chalcogenization step S2 is a selenization step. The use of another chalcogen such as sulfur is also possible.

According to one feature of this embodiment, the selenization step consists of injecting a gaseous mixture of selenium and dinitrogen, also called selenium vapor, into the second chamber 410 of the furnace 4 for the example shown in FIG. 9.

To inject the selenium vapor, the furnace 4 may comprise injection means 48 for injecting into the second chamber 410 a gaseous mixture of selenium and dinitrogen having a temperature of between 480° C. and 520° C.

According to another feature of this embodiment, the injection of the gaseous mixture of selenium and dinitrogen is performed at a volumetric flow rate of 13 standard liters per minute (SLM), plus or minus 3 standard liters per minute.

According to another feature of this embodiment, the mixture of selenium and dinitrogen comes from a source heated to 500° C., plus or minus 20° C.

It should be noted that said injection is the only addition of selenium in the formation process S according to the invention, which, unlike certain formation processes of the prior art, does not include any step of depositing a layer of selenium, for example whether by electrodeposition or by physical vapor deposition.

Selenium is particularly toxic, and particularly in the vapor phase, it is advantageous that at least the second chamber 410 of the furnace 4 is maintained at slightly below atmospheric pressure, more particularly at a pressure of 20 to 200 Pa below atmospheric pressure, because then any release of toxic vapors into the environment outside the preferably sealed second chamber 410 becomes improbable, which ensures the safety of personnel.

In addition, due to the nearly atmospheric pressure prevailing at least in the second chamber 410 of the furnace, the formation process S advantageously allows limiting the duration of the chalcogenization step S2, and more particularly the selenium vapor injection step, to 5 minutes plus or minus 1 minute, as shown in FIG. 3a, for the formation of semiconductor layers at an industrial rate, in comparison to formation processes where the annealing is done in vacuum.

That the first temperature T1 at which the selenization step begins is fixed in the manner described above is a choice which stems from observations made by the inventors. These observations are essentially related to measurements on photovoltaic cells based on semiconductor layers formed according to formation processes comprising a heating step S1 and a chalcogenization step S2. These measurements are compiled in FIGS. 5 and 6, discussed below.

The inventors have observed a strong dependency of the average yield, or average conversion efficiency, of the photovoltaic cells produced, on the temperature at which the chalcogenization step S2 begins. The relevant measurements are compiled in FIG. 5.

Presumably in a manner that is correlated to chalcogenization reaction kinematics, optimizing the rising slope of the temperature prepares the material for the actual chalcogenization reaction, in particular with atomic mobility at temperatures facilitating the incorporation of selenium into the structure of the metal precursor 2.

As illustrated in FIG. 5, for selenization start temperatures that are below 350° C. or above 540° C., the photovoltaic cells produced have an average measured yield of below 10%, while between these two temperatures an average yield of above 10% was measured. A range of values can thus be defined for the selenization start temperature, between which the average yield of photovoltaic cells is optimized. More particularly, it has been established that starting the chalcogenization at a temperature between 460° C. and 540° C., more particularly between 480° C. and 520° C., and preferably equal to 505° C., optimizes the average yield of photovoltaic cells.

The inventors have also observed that, after selenization, a given value for the ratio of the molar amount of copper to the molar amount of gallium and indium in the metal precursor 2 (this ratio sometimes denoted below as Cu/(In+Ga) for clarity) can have two corresponding values for the ratio of the total molar amount of selenium incorporated into the substrate and precursor to the molar amount of metal precursor 2 (this ratio sometimes denoted below as Se/(Cu+In+Ga) for clarity), depending on the injection temperature of the gaseous mixture of selenium and dinitrogen.

Thus, as illustrated in FIG. 6, at a value of 0.85 for the ratio Cu/(In+Ga), there is a corresponding first value, equal to 1.4, for the ratio Se/(Cu+In+Ga) obtained for an injection temperature for the gaseous mixture of between 210° C. and 400° C., and a corresponding second value, equal to 1.8, for the ratio Se/(Cu+In+Ga) obtained for an injection temperature for the gaseous mixture of between 550° C. and 580° C.

In addition, and again as illustrated in FIG. 6, the inventors have further found that, when the injection temperature of the gaseous mixture of selenium and dinitrogen increases from a temperature of 210° C. to 580° C.:
in a first phase, and more particularly for an injection temperature of the gaseous mixture of between 210° C. and 475° C., the amount of copper in the metal precursor 2 necessary to capture an only slightly varying amount of selenium to form the semiconductor layer decreases,
in a second phase, more particularly for an injection temperature of the gaseous mixture of between 540° C. and 580° C., the amount of copper in the metal precursor 2 necessary to capture an only slightly varying amount of selenium to form the semiconductor layer increases,

with, between these two phases, and more particularly for an injection temperature of the gaseous mixture of between 475° C. and 540° C., a reversal of the behavior of the amount of copper in the metal precursor 2 necessary to capture an only slightly varying amount of selenium to form the semiconductor layer 1.

Thus, the measurements represented in FIG. 6 illustrate that the formation process S according to the invention advantageously provides a wide window of stability for formation of the semiconductor layer 1, due to:
the weak dependency observed compared to the percentage of copper in the metal precursor 2, when this percentage is between 65% and 85%, and
the weak dependency observed compared to the percentage of selenium in the semiconductor layer 1 formed, when the ratio of the total molar amount of selenium incorporated into the substrate and precursor to the molar amount of metal precursor 2 is between 140% and 220%.

It should be noted that the total molar amount of selenium incorporated into the substrate and precursor is greater than the molar amount of selenium incorporated into the precursor alone, provided that the substrate effectively captures a certain molar amount of selenium. Therefore, in this case, the ratio of the molar amount of selenium incorporated into the precursor to the molar amount of metal precursor 2 is within a range of values that are less than the specified range of from 140% to 220%.

In addition, the measurements represented in FIG. 6 illustrate that it is particularly advantageous to inject the gaseous mixture of selenium and dinitrogen at a temperature between 480° C. and 520° C., preferably equal to 500° C., because at these temperatures a minimum molar amount of copper relative to the molar amount of gallium and indium in the metal precursor 2 is required for the metal precursor 2 to capture a maximum amount of selenium.

After the chalcogenization step S2 is completed, it is important to eliminate the selenium “dust”. For this purpose, the formation process S of the invention comprises, after the chalcogenization step S2, a step of injecting a neutral gas such as dinitrogen into the second chamber 410. This injection may for example last 50 seconds.

As illustrated in FIGS. 3a and 3b, the formation process S according to the invention can end in successive cooling steps as are usually implemented in most annealing operations.

The evolution of the temperature over time during these cooling steps may be controlled by: the control means 44 of the heating device 42, based on measurements made by the measurement means 46 in the second chamber 410 of the furnace 4, for example together with at least one injection of dinitrogen at a predefined temperature and for a given duration; or by the arrangement of a series of chambers at the exit from the furnace 4, including a third chamber 420 illustrated in FIG. 9, each of these maintaining a defined constant temperature and possibly a defined constant environment, the series being arranged so that the semiconductor layer 1 to be cooled passes from the third chamber 420 to the next.

The cooling in successive stages occurs for example under an inert atmosphere in successive chambers, to optimize the production rate of the formation process.

The formation process described above allows the formation of a type I-III-VI₂ semiconductor layer 1 whose characteristics are discussed below, particularly in comparison to the characteristics of a semiconductor layer obtained by a formation process comprising a chalcogenization step beginning at 580° C., as discussed in the introduction and illustrated in FIG. 3b.

Firstly, the semiconductor layer 1 obtained by the formation process according to the invention has a microstructure 10 with improved crystallinity compared to the semiconductor layer obtained by the formation process shown in FIG. 3b.

More specifically, this microstructure 10 is composed of well-defined grains 100, as illustrated in the photograph of FIG. 4a and by comparing that photograph to the photograph of FIG. 4b discussed in the introduction.

This improvement in the size of the grains of the absorber 100 is achieved by the introduction of selenium vapor when the first temperature T1 is reached, meaning at densification of the metal precursor 2.

Secondly, the grains 100 of the microstructure 10 have different sizes which are proportional to the full width at half maximum of the XRD peak of the CIGSe semiconductor layer 1 for the crystallographic planes identified by Miller indices {112}. As illustrated in FIG. 10, the full width at half maximum (FWHM) is greatly increased when the selenium vapor is introduced at an injection temperature higher than T1 where T1 is equal to 505° C., corresponding to smaller and less clearly formed crystallites.

As illustrated in FIG. 7, one can see that the grains 100 of the microstructure 10 obtained by the formation process S according to the invention allow achieving, for the same range of values for the ratio Se/(Cu+In+Ga), greater conversion efficiency than what can be achieved with the formation process shown in FIG. 3b. More particularly, the average conversion efficiency achieved with the formation process S according to the invention is over 12%, while that achieved with the formation process illustrated in FIG. 3b is about 8%, a gain of about 4% in conversion efficiency.

In addition, the grain size distribution is smaller and better controlled, than what can be obtained by the formation process shown in FIG. 3b.

This assertion is founded on an analysis of the compiled measurements in FIGS. 8a and 8b. These figures are graphs placed adjacent to each other to facilitate comparison. Each of these graphs represents the efficiency of photovoltaic cells as a function of the ratio of Cu/(In+Ga) in the metal precursor 2, particularly when this ratio varies between 0.6 and 1.2. The graph of FIG. 8a compiles measurements collected for a photovoltaic cell obtained by the formation process according to the invention, and the graph of FIG. 8b compiles measurements collected for a photovoltaic cell obtained by the formation process according to the prior art illustrated in FIG. 3b.

It is immediately apparent, particularly within the two horizontal lines joined by a vertical double arrow on each graph, that even by limiting the range of values for the ratio of Cu/(In+Ga) to values below 0.9 for the purposes of this analysis, the dispersion in the conversion efficiency is markedly reduced by the formation process according to the invention in comparison to the formation process shown in FIG. 3b.

Thirdly, the semiconductor layer 1 comprises several layers of different compositions. More particularly, it can advantageously consist of a mixture of three phases, while the semiconductor layer formed by the process illustrated in FIG. 3b has only two as discussed in the introduction.

For example, and as illustrated in FIG. 2d, the semiconductor layer 1 comprises three layers: an upper layer of composition CuIn_{0.65}Ga_{0.35}Se_{2,} an intermediate layer located under the upper layer and of composition CuIn_{0.7}Ga_{0.3}Se₂, and a lower layer 11 beneath the intermediate layer and of composition CuGaSe₂.

It is therefore observed that the gallium continued to diffuse to the lower layers of the stack constituting the metal precursor 2, during the heating S1 and chalcogenization S2 steps.

In addition, it should be noted that a certain amount of selenium was captured by the molybdenum initially constituting the substrate 3, to form a layer of composition MoSe₂ under the lower layer 11, as illustrated in FIG. 2d.

The formation of the lower layer of composition CuGaSe₂ is therefore advantageous in that the adhesion of the semiconductor layer 1 to the layers on which it sits, particularly to the layer of composition MoSe₂ shown in FIG. 2d, is improved.

It will be understood from the foregoing that different ranges for the temperature, temperature increase slope, volumetric flow rate and/or duration of injection, as presented above, may be variable depending on the parameters to be considered such as layer thicknesses, and/or substrate dimensions, and/or composition of the inert atmosphere, and/or the amount of gallium.

1. A process for forming a type I-III-VI₂ semiconductor layer by heat treatment and chalcogenization, in at least one chamber of a furnace, of a type I-III metal precursor deposited on a substrate, the process comprising:
a heating step under an inert atmosphere, during which the temperature uniformly increases to a first temperature of between 460° C. and 540° C., to enable densification of the metal precursor, and
a chalcogenization step beginning at said first temperature and during which the temperature continues to increase to a second temperature, for stabilization, of between 550° C. and 600° C., to enable formation of the semiconductor layer.

2. The process according to claim 1, wherein the first temperature is between 480° C. and 520° C.

3. The process according to claim 1, wherein the first temperature is equal to 505° C.

4. The process according to claim 1, wherein, during the heating step, the temperature increases at a rate of 3.5° C./sec, plus or minus 1° C./sec.

5. The process according to claim 1, wherein the chalcogenization step consists of a selenization step by injection of a gaseous mixture of selenium and dinitrogen into at least one chamber of the furnace.

6. The process according to claim 5, wherein the gaseous mixture of selenium and dinitrogen is obtained by heating selenium to a temperature of between 480° C. and 520° C. to obtain a high partial pressure of the selenium.

7. The process according to claim 5, wherein the injection of the gaseous mixture of selenium and dinitrogen occurs at a volumetric flow rate of 13 standard liters per minute, plus or minus 3 standard liters per minute.

8. The process according to any claim 1, wherein the chalcogenization step lasts 5 minutes, plus or minus 1 minute.

9. The process according to claim 1, wherein the ratio of the total amount of chalcogen incorporated into the substrate and precursor to the amount of metal precursor is between 1.4 and 2.2.

10. The process according to claim 1, wherein, the furnace comprising at least one series of chambers, the heating step is carried out in a first chamber of the series and the chalcogenization step is carried out in a second chamber of the series.

11. The process according to claim 1, wherein at least the second chamber of the furnace is maintained at a pressure that is 20 to 200 Pa below atmospheric pressure.

12. The process according to claim 1, wherein the second temperature, for stabilization, is between 570° C. and 590° C.

13. A type I-III-VI₂ semiconductor layer obtained by the formation process according to claim 1, having a microstructure composed of grains of different sizes corresponding to a full width at half maximum of the {112} XRD peak of the CIGSe of between 0.16° and 0.18°.

14. The semiconductor layer according to claim 13, wherein it comprises several layers of different compositions, including a lower layer which is a CuGaSe₂ layer.

15. A furnace for carrying out the formation process according to claim 1, comprising:
at least a first chamber and a second chamber,
means of conveyance from one chamber to the next,
a heating device for each chamber,
control means for each heating device, and
measurement means for measuring the temperature in each chamber, the latter communicating the temperature measurements for each chamber to the control means for the purposes of controlling each heating device, so as to ensure a uniform increase in temperature in the first chamber to a first temperature of between 460° C. and 540° C., and the maintaining of the temperature in the second chamber at a second temperature, for stabilization, of between 550° C. and 600° C.,
the furnace further comprising injection means for injecting an inert gas into the first chamber, and
injection means for injecting, into the second chamber, a gaseous mixture of selenium and dinitrogen having a temperature of between 480° C. and 520° C.
